(19) United States
(12) Patent Application Publication
(10) Pub. No.: US 2025/0364415 A1
(43) Pub. Date: Nov. 27, 2025

(54) SEMICONDUCTOR DEVICE

(71) Applicant: Samsung Electronics Co., Ltd., Suwon-si (KR)

(72) Inventors: Juho LEE, Suwon-si (KR); Sungjin KIM, Suwon-si (KR); Jeon Il LEE, Suwon-si (KR); Daewon HA, Suwon-si (KR)

(73) Assignee: Samsung Electronics Co., Ltd., Suwon-si (KR)

(21) Appl. No.: 19/011,959

(22) Filed: Jan. 7, 2025

(30) Foreign Application Priority Data
May 23, 2024 (KR) 10-2024-0067372

(51) Int. Cl. H01L 23/528; H10D 30/63; H10D 62/40

(52) U.S. Cl. CPC H01L 23/5283; H10D 30/63; H10D 62/402

(57) ABSTRACT

Some example embodiments are directed to semiconductor device that includes a first bit line extending in a first direction, a first semiconductor pattern on the first bit line and including vertical portions and a horizontal portion, first word lines spaced apart from each other in the first direction on the horizontal portion and extending in a second direction, second bit lines spaced apart from each other in the first direction and on the first word lines and extending in the second direction, a gate insulating pattern between the vertical portions of the first semiconductor pattern and the first word lines and extending between the vertical portions and the second bit lines, a second semiconductor pattern on the second bit lines, and a second word line extending in the first direction on the second semiconductor pattern. The first word lines and the second bit lines vertically overlap each other.

### CROSS-REFERENCE TO RELATED APPLICATIONS

This U.S. non-provisional patent application claims priority under 35 U.S.C. § 119 to Korean Patent Application No. 10-2024-0067372, filed on May 23, 2024, in the Korean Intellectual Property Office, the entire contents of which are hereby incorporated by reference.

### BACKGROUND

Example embodiments relate to semiconductor devices including vertical channel transistors and methods of manufacturing the same.

Semiconductor devices are used in the electronic industry for various purposes, due at least in part due to the relatively small size, multifunctional capabilities, and/or low-cost characteristics of semiconductor devices. Increased integration of semiconductor memory devices has been studied. Semiconductor memory devices having increased integration may include unit cells each occupying a smaller planar area. In some cases, manufacturing costs associated with manufacturing semiconductor devices having increased integration may be increased based at least in part upon increased costs of process equipment used to manufacture such semiconductor devices having increased integration.

### SUMMARY

Example embodiments of the inventive concepts are directed to semiconductor devices including vertical channel transistors, and methods of manufacturing the same. Vertical channel transistors improve or increase device integration, and thereby reduce costs associated with manufacturing semiconductor devices. Additionally or alternatively, vertical channel transistors have improved resistance properties and/or current driving capability, and thereby improve, e.g., optimize, the performance of semiconductor devices including the vertical channel transistors.

The problems to be solved by the example embodiments according to the inventive concepts disclosed herein are not limited to the problems mentioned above, and other problems not mentioned can also be solved using the example embodiments as will be clearly understood by those skilled in the art from the description below.

A semiconductor device according to some example embodiments of the inventive concepts may include a first bit line extending in a first direction on a substrate, a first semiconductor pattern on the first bit line, the first semiconductor pattern including vertical portions facing each other in the first direction and a horizontal portion connecting the vertical portions to each other, first word lines spaced apart from each other in the first direction on the horizontal portion and extending in a second direction that is parallel to an upper surface of the substrate and intersects the first direction, second bit lines spaced apart from each other in the first direction and on the first word lines, and extending in the second direction, a gate insulating pattern between the vertical portions of the first semiconductor pattern and the first word lines and extending between the vertical portions and the second bit lines, a second semiconductor pattern on the second bit lines, and a second word line extending in the first direction on the second semiconductor pattern. The first word lines and the second bit lines vertically overlap each other.

A semiconductor device according to some example embodiments of the inventive concepts may include a first bit line extending in a first direction on a substrate, a first semiconductor pattern extending on the first bit line in a vertical direction perpendicular to an upper surface of the substrate, a first word line extending on an inner surface of the first semiconductor pattern in a second direction that is parallel to the upper surface of the substrate and intersects the first direction, a second bit line spaced apart from the first word line in the vertical direction and extending in the second direction on the inner surface of the first semiconductor pattern, a gate insulating pattern between the first semiconductor pattern and the first word line and between the first semiconductor pattern and the second bit line, a second semiconductor pattern on the second bit line, and a second word line extending in the first direction on the second semiconductor pattern. The first word line and the second bit line overlap each other in the vertical direction.

A semiconductor device according to some example embodiments of the inventive concepts may include a first bit line extending in a first direction on a substrate, first insulating patterns on the first bit line and spaced apart from each other in the first direction, a first semiconductor pattern on the first bit line and between the first insulating patterns, the first semiconductor pattern including vertical portions extending in a vertical direction perpendicular to an upper surface of the substrate and facing each other in the first direction, and a horizontal portion connecting the vertical portions to each other, first word lines spaced apart from each other in the first direction and on the horizontal portion, and extending in a second direction parallel to the upper surface of the substrate and intersecting the first direction, second bit lines spaced apart from each other in the first direction on the first word lines and extending in the second direction, a gate insulating pattern between the vertical portions of the first semiconductor pattern and the first word lines, between the vertical portions of the first semiconductor pattern and the second bit lines, and extending on the horizontal portion, a second semiconductor pattern on the second bit lines, and a second word line extending in the first direction on the second semiconductor pattern. The first word lines and the second bit lines are spaced apart from each other in the vertical direction and have a lower insulating pattern therebetween. The lower insulating pattern covers the first word lines, and the first word lines and the second bit lines overlap each other in the vertical direction.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram of a memory cell, according to some example embodiments of the inventive concepts.

FIG. 2 is a plan view of a semiconductor device, according to some example embodiments of the inventive concepts.

FIGS. 3A, 3B, and 3C are cross-sectional views of the semiconductor device of FIG. 2, according to some example embodiments of the inventive concepts, taken along lines A-A′, B-B′, and C-C′ in FIG. 2, respectively.

FIGS. 4A, 4B, 4C, 5A, 5B, 5C, 6A, 6B, 6C, 7A, 7B, 7C, 8A, 8B, 8C, 9A, 9B, 9C, 10A, 10B, and 10C are cross-sectional views showing operations in a method of manufacturing the semiconductor device of FIGS. 3A, 3B, and 3C.

FIGS. 11 and 12 are cross-sectional views illustrating operations in a method of manufacturing a semiconductor device, according to some example embodiments of the inventive concepts.

FIGS. 13 and 14 are cross-sectional views of semiconductor devices, according to some example embodiments of the inventive concepts.

### DETAILED DESCRIPTION

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, with reference to the drawings, a semiconductor memory device and a method of manufacturing the same according to some embodiments of the inventive concepts will be described in detail.

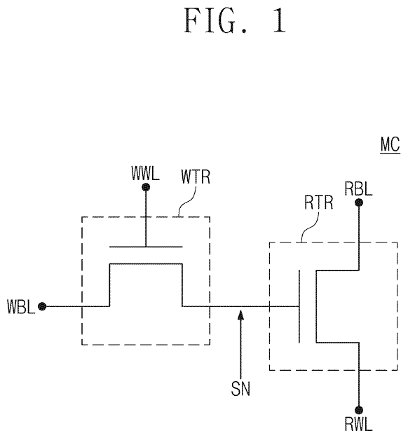

FIG. 1 is a circuit diagram of a memory cell MC, according to some example embodiments of the inventive concepts.

Referring to FIG. 1, the memory cell MC may include a write transistor WTR and a read transistor RTR connected thereto. A semiconductor device may include a plurality of memory cells (MCs) arranged two-dimensionally or three-dimensionally. The write transistor WTR may include a write word line WWL connected to a gate terminal of the write transistor WTR and a write bit line WBL connected to a source terminal of the write transistor WTR. The read transistor RTR may include a read word line RWL and a read bit line RBL respectively connected to source/drain terminals of the read transistor RTR.

A drain terminal of the write transistor WTR may be connected to a gate terminal of the read transistor RTR. The drain terminal of the write transistor WTR may be referred to as a storage node SN. The storage node SN may function as a gate of the read transistor RTR. The storage node SN may store electric charges.

In some example embodiments, a programming operation of the memory cell MC may include applying a voltage to the write word line WWL and the write bit line WBL to turn on the write transistor WTR and transmitting (charging) an electrical signal (charge) to the storage node SN. Accordingly, the electrical signal (or charge) of the write bit line WBL may be stored in the storage node SN, and as a result, a threshold voltage of the read transistor RTR may be varied. For example, a read operation of the memory cell MC may include turning off the write transistor WTR, setting the read word line RWL to 0V or about 0V, and applying a voltage to the read bit line RBL. The electrical signals (charges) stored in the storage node SN may be read through the current flowing in the read transistor RTR.

The semiconductor device including the memory cell MC may be referred to as a two transistor-zero capacitor (2T-0C) memory device. The semiconductor device, according to some example embodiments, may not include a separate or independent or discrete capacitor for storing charge(s), and a parasitic capacitance of the read transistor RTR may function as the capacitor (or storage element). Due to the absence of a separate capacitor, the relatively large area consumed by the capacitor is reduced and/or minimized, thereby increasing and/or improving integration of the semiconductor device.

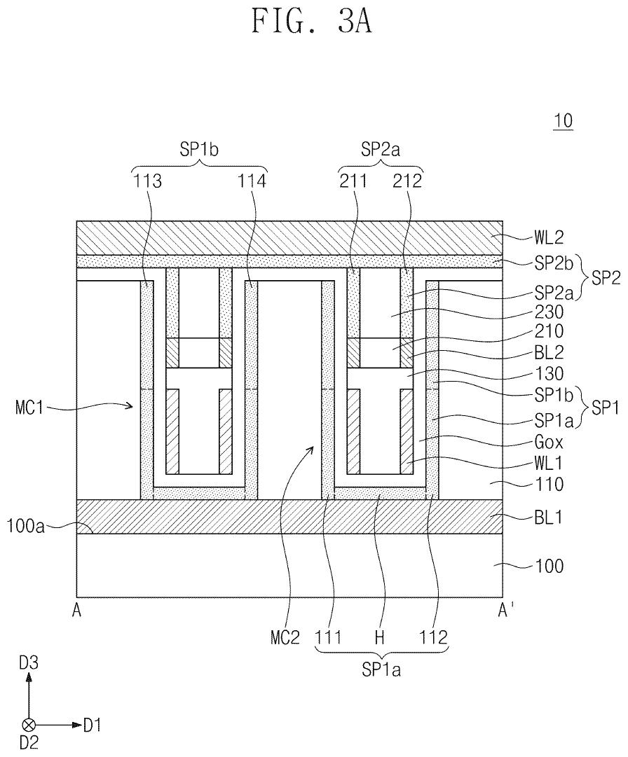

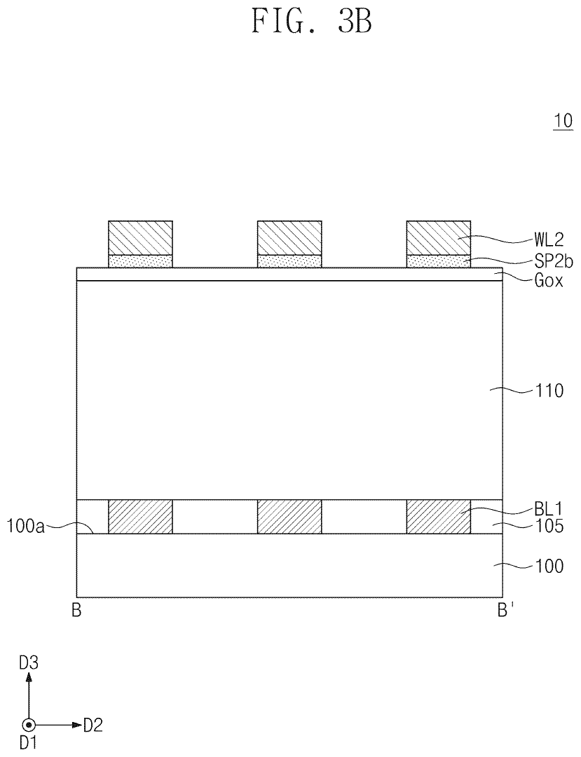

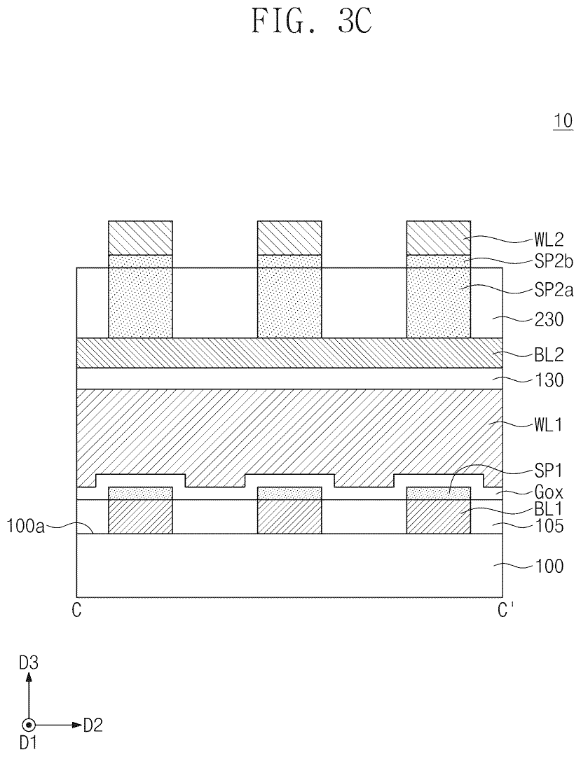

The 2T-0C memory device, according to some example embodiments, may include a vertical channel transistor (VCT). The vertical channel transistor may refer to a structure in which a channel length extends in a direction perpendicular or transverse to an upper surface of the substrate (e.g., substrate 100 in FIGS. 3A-3C).

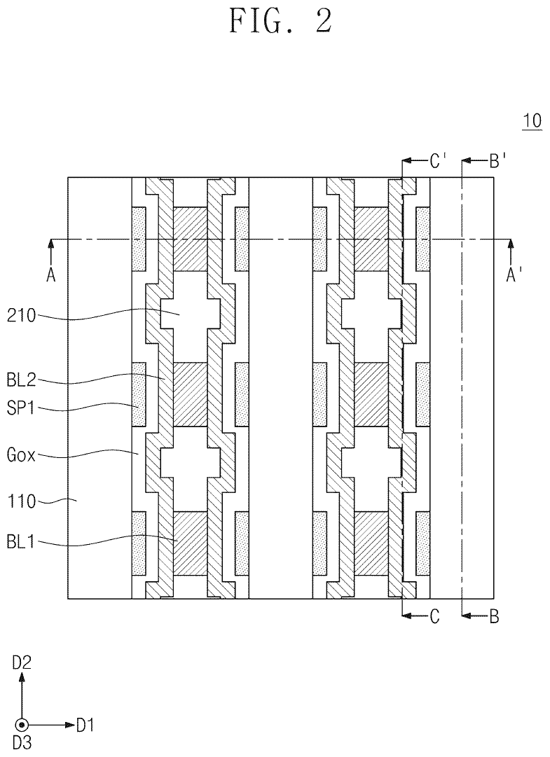

FIG. 2 is a plan view of a semiconductor device 10, according to some example embodiments of the inventive concepts. FIGS. 3A to 3C are cross-sectional views of the semiconductor device 10 of FIG. 2, according to some example embodiments of the inventive concepts, taken along lines A-A′, B-B′, and C-C′ in FIG. 2, respectively. The upper insulating layer 230, second semiconductor pattern SP2, and second word line WL2 of FIG. 3A (discussed below) have been omitted in FIG. 2 for the sake of clarity of illustration. The plurality of first bit lines BL1 are below the second insulating pattern 210, and in FIG. 2, the plurality of first bit lines BL1 are depicted for sake of explaining the semiconductor device 10.

Referring to FIGS. 2 and 3A to 3C, the semiconductor device 10, according to some example embodiments of the inventive concepts, may include a substrate 100. The substrate 100 may be a semiconductor substrate. The substrate 100 may be or include, for example, a silicon substrate, a germanium substrate, or a silicon-germanium substrate. For the purposes of discussion, the semiconductor device 10 is illustrated having two memory cells MC1 and MC2. However, the semiconductor device 10 may include a single memory cell (MC) or more than two memory cells (MCs).

A plurality of first bit lines BL1 may be disposed on the substrate 100. The first bit lines BL1 may extend in a first direction D1 and be spaced apart from each other in a second direction D2. For the purposes of discussion, the first direction D1 and the second direction D2 may be directions parallel to an upper surface 100a of the substrate 100 and crossing each other. The first direction D1 and the second direction D2 may also be referred to as horizontal directions D1 and D2. A third direction D3 may be perpendicular to the upper surface 100a of the substrate 100. The third direction D3 may also be referred to as a vertical direction D3. For example, the first direction D1, the second direction D2, and the third direction D3 may be orthogonal to each other.

Lower spacers 105 may be disposed on the substrate 100 and between the first bit lines BL1. The lower spacers 105 may extend in the first direction D1 and may be spaced apart from each other in the second direction D2. The lower spacers 105 may be provided between adjacent first bit lines BL1, respectively. Upper surfaces of the lower spacers 105 may be coplanar with upper surfaces of the first bit lines BL1.

The first bit line BL1 may include, for example, at least one of doped polysilicon, metal (e.g., Al, Cu, Ti, Ta, Ru, W, Mo, Pt, Ni, Co), conductive metal nitride (e.g. TiN, TaN, WN, NbN, TiAlN, TiSiN, TaSiN, RuTiN), conductive metal silicide or conductive metal oxide (e.g. PtO, RuO₂, IrO₂, SrRuO₃ (SRO), (Ba,Sr)RuO₃ (BSRO), CaRuO₃ (CRO), LSCo), combinations thereof, and the like. However, example embodiments are not limited thereto, and first bit line BL1 may include other conductive material. The first bit line BL1 may include a single layer or multiple layers of the above-described materials. In some example embodiments, the first bit line BL1 may include a two-dimensional semiconductor material, for example, the two-dimensional material may be graphene, carbon nanotube, or a combination thereof.

The lower spacers 105 may include a plurality of stacked insulating layers. The lower spacers 105 may include, for example, an insulating material such as silicon oxide, silicon nitride, silicon oxynitride, and/or a low dielectric material. For the purposes of discussion, low dielectric material may refer to a material having a lower dielectric constant than silicon oxide. In some example embodiments, the low dielectric material may include a dielectric material with a dielectric constant of 3.9 or less, and may include a material doped with silicon oxide with fluorine (F) or carbon (C).

The semiconductor device 10 may include a plurality of first semiconductor patterns SP1 each disposed on a corresponding one of the first bit lines BL1. The first semiconductor patterns SP1 may be spaced apart from each other in the first and second directions D1 and D2.

The first semiconductor pattern SP1 may include vertical portions 111, 112, 113, and 114 facing each other in the first direction D1, and a horizontal portion H connecting the vertical portions 111, 112, 113, and 114 to each other. The vertical portions 111, 112, 113, and 114 may extend in the vertical direction D3. The vertical portions 111, 112, 113, and 114 may include a first vertical portion 111 and a second vertical portion 112 adjacent to the horizontal portion H and facing each other in the first direction D1. The vertical portions may further include a third vertical portion 113 extending from the first vertical portion 111 in the vertical direction D3, and a fourth vertical portion 114 extending from the second vertical portion 112 in the vertical direction D3. The third vertical portion 113 and the fourth vertical portion 114 may be spaced apart from each other in the first direction D1. In some example embodiments, the horizontal portion H may be adjacent to lower portions of the first vertical portion 111 and the second vertical portion 112 and may connect the first and second vertical portions 111 and 112.

The first semiconductor pattern SP1 may include a first portion SP1a and a second portion SP1b. The first portion SP1a may include the first vertical portion 111, the second vertical portion 112, and the horizontal portion H. The second portion SP1b may include the third vertical portion 113 and the fourth vertical portion 114.

The horizontal portion H of the first semiconductor pattern SP1 may be disposed on an upper surface of the first bit line BL1. The horizontal portion H may be in contact (e.g., in direct contact) with the first bit line BL1. According to some example embodiments, a lower surface of the horizontal portion H may be in contact with the upper surface of the first bit line BL1. The first semiconductor pattern SP1 may be electrically connected to the first bit line BL1. The semiconductor device, according to some example embodiments, may have a structure in which a pair of vertical channel transistors share one bit line.

The first semiconductor pattern SP1 may be or include an oxide semiconductor. In some example embodiments, the oxide semiconductor may be or include at least one of InₓGa_{y}Zn_{z}O, InₓTi_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, Ga_{y}Zn_{z}O and InₓGa_{y}O, combinations thereof, and the like, However, example embodiments are not limited thereto, and the first semiconductor pattern SP1 may include other types of oxide semiconductors. For purposes of discussion, the first semiconductor pattern SP1 may be considered to be or include indium gallium zinc oxide (IGZO). The first semiconductor pattern SP1 may include a single layer or multiple layers of an oxide semiconductor. The first semiconductor pattern SP1 may include an amorphous, crystalline, or polycrystalline oxide semiconductor. In some example embodiments, the first semiconductor pattern SP1 may have a band gap energy greater than that of silicon. In some example embodiments, the first semiconductor pattern SP1 may have a bandgap energy of about 1.5 eV to 5.6 eV. In some example embodiments, the first semiconductor pattern SP1 may have a band gap energy of about 2.0 eV to 4.0 eV. In some example embodiments, the first semiconductor pattern SP1 may be polycrystalline or amorphous, but is not limited thereto. In some example embodiments, the first semiconductor pattern SP1 may include a two-dimensional semiconductor material. In some example embodiments, the two-dimensional semiconductor material may include graphene, carbon nanotube, or a combination thereof.

According to some example embodiments, the first portion SP1a of the first semiconductor pattern SP1 may be crystalline, and the second portion SP1b may be amorphous. In some example embodiments, the first portion SP1a may have a relatively higher oxygen concentration than that of the second portion SP1b. In some example embodiments, the oxygen concentrations of the first and second vertical portions 111 and 112 of the first semiconductor pattern SP1 may be relatively higher than that of the third and fourth vertical portions 113 and 114. In some example embodiments, the third and fourth vertical portions 113 and 114 may be relatively more metallic compared to the first and second vertical portions 111 and 112.

First word lines WL1 may be disposed between the first vertical portion 111 and the second vertical portion 112 on the horizontal portion H. The first word lines WL1 may extend in the second direction D2 and may be spaced apart from each other in the first direction D1. The first word lines WL1 may be respectively disposed on inner surfaces of the first semiconductor pattern SP1. In some example embodiments, the inner surfaces of the first semiconductor pattern SP1 may be surfaces where vertical portions of the first semiconductor pattern SP1 face each other. The first vertical portion 111 and the second vertical portion 112 may be adjacent to the first word lines WL1, respectively. The first word lines WL1 may be adjacent to the first portion SP1a of the first semiconductor pattern SP1.

According to some example embodiments, each of the first and second vertical portions 111 and 112 of the first semiconductor pattern SP1 may have side surfaces that face each other in the second direction D2. Each of the first word lines WL1 may extend in the second direction D2 on each inner surface of the first and second vertical portions 111 and 112. Each of the first word lines WL1 may protrude (or have a thickness) in the first direction D1 to cover (or overlap) the side surfaces of the first and second vertical portions 111 and 112, respectively.

The first word lines WL1 may include, for example, at least one of doped polysilicon, metal (e.g., Al, Cu, Ti, Ta, Ru, W, Mo, Pt, Ni, Co), conductive metal nitride (e.g. TiN, TaN, WN, NbN, TiAlN, TiSiN, TaSiN, RuTiN), conductive metal silicide or conductive metal oxide (e.g. PtO, RuO₂, IrO₂, SrRuO₃ (SRO), (Ba,Sr)RuO₃ (BSRO), CaRuO₃ (CRO), LSCo). However, example embodiments are not limited thereto, and the first word lines WL1 may include other types of conductive materials depending on application and/or design. The first word lines WL1 may include a single layer or multiple layers of the above-described materials. In some example embodiments, the first word lines WL1 may include a two-dimensional semiconductor material, for example, graphene, carbon nanotube, or a combination thereof.

A gate insulating pattern Gox may be interposed between the first semiconductor pattern SP1 and the first word lines WL1. The gate insulating pattern Gox may be interposed between the first and second vertical portions 111 and 112 of the first semiconductor pattern SP1 and the first word lines WL1, and may extend between the horizontal portion H and the first word lines WL1. The gate insulating pattern Gox may cover side surfaces of the horizontal portion H of the first semiconductor pattern SP1 facing in the second direction D2 and may extend on an upper surface of the lower spacer 105. The gate insulating pattern Gox may extend on inner surfaces of each of the third and fourth vertical portions 113 and 114 in the vertical direction D3. The inner surfaces of the third and fourth vertical portions 113 and 114 may be side surfaces facing each other in the first direction D1.

The gate insulating pattern Gox may include at least one of silicon oxide, silicon oxynitride, and a high dielectric material having a higher dielectric constant than silicon oxide. The high dielectric material may include metal oxide or metal oxynitride. For example, the gate insulation pattern Gox may include the high dielectric material including at least one of HfO₂, HfSiO, HfSiON, HfTaO, HfTiO, HfZrO, ZrO₂, and Al₂O₃. However, example embodiments are not limited thereto, and other dielectric materials having the desired dielectric constant may be used depending on application and/or design.

A lower insulating pattern 130 may be disposed between the first word lines WL1 and on the gate insulating pattern Gox. The lower insulating pattern 130 may extend in the second direction D2. The lower insulating pattern 130 may extend onto upper surfaces of the first word lines WL1 and cover the first word lines WL1. The first word lines WL1 may be spaced apart from each other in the first direction D1 with the lower insulating pattern 130 interposed therebetween. The lower insulating pattern 130 may include, for example, an insulating material such as silicon oxide, silicon nitride, silicon oxynitride, and/or a low dielectric material.

A second bit line BL2 may be disposed on each first word lines WL1. The second bit lines BL2 may extend in the second direction D2 and may be spaced apart from each other in the first direction D1. The second bit lines BL2 may be disposed on the lower insulating pattern 130. The second bit lines BL2 may be respectively disposed on inner surfaces of the first semiconductor pattern SP1. The second bit lines BL2 and the first word lines WL1 may be spaced apart from each other in the vertical direction D3 with the lower insulating pattern 130 interposed therebetween. The first word lines WL1 and the second bit lines BL2 may overlap each other in the vertical direction D3.

The second bit lines BL2 may be adjacent to the third vertical portion 113 and the fourth vertical portion 114 of the first semiconductor pattern SP1, respectively. The second bit lines BL2 may be adjacent to the second portion SP1b of the first semiconductor pattern SP1.

According to some example embodiments, each of the third and fourth vertical portions 113 and 114 of the first semiconductor pattern SP1 may have side surfaces that face each other in the second direction D2. Each of the second bit lines BL2 may extend in the second direction D2 on each inner surface of the third and fourth vertical portions 113 and 114. Each of the second bit lines BL2 may protrude (or have a thickness) in the first direction D1 to cover (or overlap) the side surfaces of the third and fourth vertical portions 113 and 114, respectively.

The second bit lines BL2 may include, for example, at least one of doped polysilicon, metal (e.g., Al, Cu, Ti, Ta, Ru, W, Mo, Pt, Ni, Co), conductive metal nitride (e.g. TiN, TaN, WN, NbN, TiAlN, TiSiN, TaSiN, RuTiN), conductive metal silicide or conductive metal oxide (e.g. PtO, RuO₂, IrO₂, SrRuO₃ (SRO), (Ba,Sr)RuO₃ (BSRO), CaRuO₃ (CRO), LSCo). However, example embodiments are not limited thereto and the second bit lines BL2 may include other conductive materials. The second bit lines BL2 may include a single layer or multiple layers of the above-described materials. In some example embodiments, the second bit lines BL2 may include a two-dimensional semiconductor material. For example, the two-dimensional semiconductor material may be graphene, carbon nanotube, or a combination thereof.

A first insulating pattern 110 may be interposed between first semiconductor patterns SP1 adjacent to each other in the first direction D1. A plurality of first insulating patterns 110 may be provided. The first insulating patterns 110 may extend in the second direction D2 across the first bit line BL1 and may be spaced apart from each other in the first direction D1. The first insulating pattern 110 may be in contact with outer surfaces of the vertical portions 111, 112, 113, and 114 of the first semiconductor pattern SP1. An upper surface of the first insulating pattern 110 may be coplanar with the upper surfaces of the third and fourth vertical portions 113 and 114 of the first semiconductor pattern SP1. In some example embodiments, the first insulating pattern 110 may include at least one of silicon oxide, silicon nitride, silicon oxynitride, and a low dielectric material. In some example embodiments, the first insulating pattern 110 may be or include a single layer or multiple layers.

A second insulating pattern 210 may be disposed between the second bit lines BL2. An upper surface of the second insulating pattern 210 may be coplanar with upper surfaces of the second bit lines BL2. The second insulating pattern 210 may extend in the second direction D2. The second bit lines BL2 may be spaced apart from each other in the first direction D1 with the second insulating pattern 210 therebetween.

The second semiconductor pattern SP2 may be disposed on the second bit lines BL2. The second semiconductor pattern SP2 may include upper vertical portions SP2a extending in the vertical direction D3 and upper horizontal portions SP2b extending on the upper vertical portions SP2a in the first direction D1. The upper vertical portions SP2a may include a first upper vertical portion 211 and a second upper vertical portion 212 spaced apart from each other in the first direction D1. A plurality of upper vertical portions SP2a of the second semiconductor pattern SP2 may be provided. The plurality of upper vertical portions SP2a may be connected by the upper horizontal portion SP2b. The second semiconductor pattern SP2 may be electrically connected to the second bit lines BL2.

According to some example embodiments, the second semiconductor pattern SP2 may include substantially the same material as the first semiconductor pattern SP1. According to some example embodiments, the second semiconductor pattern SP2 may include a different material from the first semiconductor pattern SP1. In some example embodiments, the first semiconductor pattern SP1 may include an oxide semiconductor, and the second semiconductor pattern SP2 may include doped polycrystalline silicon. In some example embodiments, the doped polycrystalline silicon may be N-type doped polycrystalline silicon.

An upper insulating pattern 230 may be disposed between the upper vertical portions SP2a of the second semiconductor pattern SP2. The upper insulating pattern 230 may be disposed on the second insulating pattern 210. The upper insulating pattern 230 may extend in the second direction D2. The upper insulating pattern 230 may extend from the second insulating pattern 210 to a lower surface of the upper horizontal portion SP2b in the vertical direction D3.

The gate insulating pattern Gox may extend between the second bit lines BL2 and the third vertical portions 113 and between the second bit lines BL2 and the fourth vertical portion 114. The gate insulating pattern Gox may extend between the third vertical portions 113 and the upper vertical portions SP2a of the second semiconductor pattern SP2, and between the fourth vertical portion 114 and the upper vertical portions SP2a of the second semiconductor pattern SP2. The gate insulating pattern Gox may extend on upper surfaces of the first insulating patterns 110 and on the upper surfaces of the third vertical portions 113 and the fourth vertical portions 114. The gate insulating pattern Gox may extend between the upper surfaces of the first insulating patterns 110 and the upper horizontal portion SP2b of the second semiconductor pattern SP2, and between the upper surfaces of the third vertical portions 113 and the fourth vertical portions 114 and the upper horizontal portion SP2b of the second semiconductor pattern SP2.

The semiconductor device 10 may include a plurality of second word lines WL2 and each second word line WL2 may be disposed on a corresponding upper horizontal portion SP2b of the second semiconductor pattern SP2. The second word lines WL2 may extend in the first direction D1 and be spaced apart from each other in the second direction D2. The second word line WL2 may vertically overlap the upper horizontal portion SP2b of the second semiconductor pattern SP2 in the vertical direction D3. The second word line WL2 may vertically overlap the first bit line BL1. The second semiconductor pattern SP2 may be electrically connected to the second word line WL2.

In some example embodiments, the second word lines WL2 may be or include at least one of doped polysilicon, metal (e.g., Al, Cu, Ti, Ta, Ru, W, Mo, Pt, Ni, Co), conductive metal nitride (e.g. TiN, TaN, WN, NbN, TiAlN, TiSiN, TaSiN, RuTiN), conductive metal silicide or conductive metal oxide (e.g. PtO, RuO₂, IrO₂, SrRuO₃ (SRO), (Ba,Sr)RuO₃ (BSRO), CaRuO₃ (CRO), LSCo). However, example embodiments are not limited thereto, and in some example embodiments the second word lines WL2 may be or include other conductive materials depending on application and/or design. In some example embodiments, the second word lines WL2 may include a single layer or multiple layers of the above-described materials. In some example embodiments, the second word lines WL2 may include a two-dimensional semiconductor material, for example, graphene, carbon nanotube, or a combination thereof.

The memory cells MC1 and MC2 in the semiconductor device 10, according to some example embodiments, may not include a separate or independent or discrete capacitor. In some example embodiments, the first word line WL1, the first bit line BL1, and the first semiconductor pattern SP1 may form one (or a first) transistor of a memory cell MC1 (or MC2). The second word line WL2, the second bit line BL2, the second semiconductor pattern SP2, and the second portion SP1b of the first semiconductor pattern SP1 may form the other (or a second) transistor of the memory cell MC1 (or MC2). The one (or first) transistor may correspond to the write transistor WTR described with reference to FIG. 1, and the other (or second) transistor may correspond to the read transistor RTR. The second portion SP1b of the first semiconductor pattern SP1 may correspond to the storage node SN described with reference to FIG. 1. The second portion SP2a of the second semiconductor pattern SP2 may function as a gate of the read transistor RTR. The second portion SP1b of the first semiconductor pattern SP1 may store an electrical signal (or charge).

According to some example embodiments of the inventive concepts, as the semiconductor device does not include a separate or independent or distinct capacitor, the area of the semiconductor device may be reduced. Accordingly, the semiconductor device may occupy a relatively smaller area on a semiconductor substate and thus relatively higher device integration may be achieved. The first word lines WL1 may surround the first and second vertical portions 111 and 112 of the first semiconductor pattern SP1 in three directions. Accordingly, electrical characteristics and/or reliability of the write transistor WTR may be improved. The 2-transistor-0-capacitor (2T0C) structure of the semiconductor device has a relatively lower off-current, which may improve charge retention of the semiconductor device.

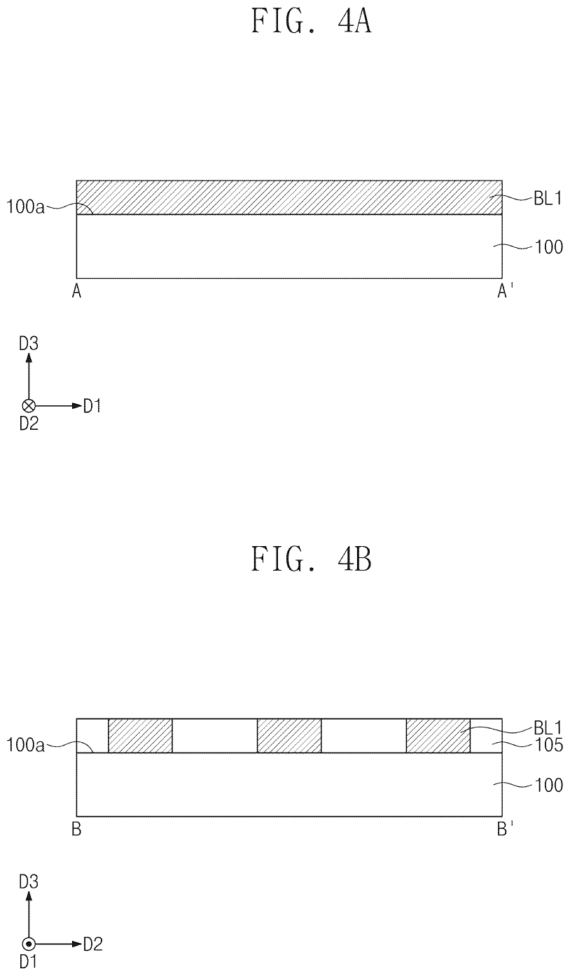

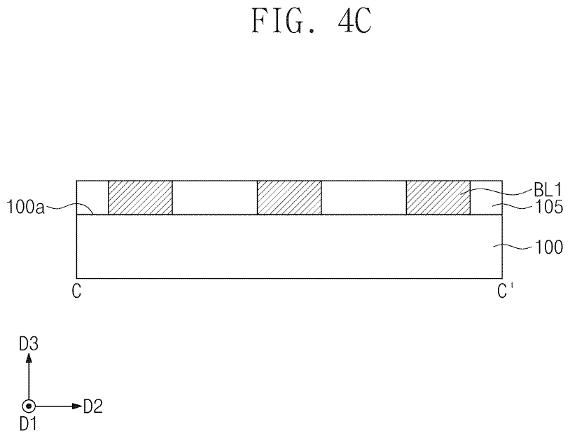

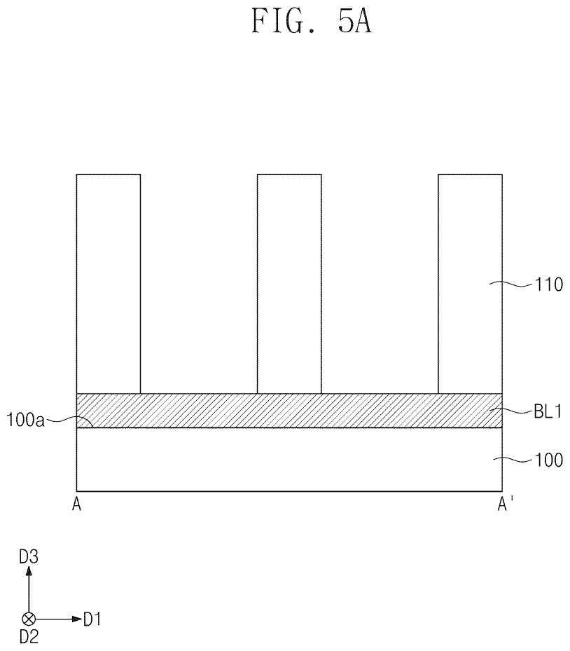

FIGS. 4A to 10C are cross-sectional views illustrating the operations in a manufacturing method of the semiconductor device of FIGS. 3A to 3C. The cross-sectional views of the operations in FIGS. 4A-4C, 5A-5C, 6A-6C, 7A-7C, 8A-8C, 9A-9C and 10A-10C correspond to lines A-A′, B-B′, and C-C′ of FIG. 2, respectively. For the purposes of discussion, a method of manufacturing the semiconductor device of FIGS. 3A to 3C will be described with reference to FIGS. 2 and 4A to 10C. It is understood that additional operations can be provided before, during, and after the operations in FIGS. 4A to 10C, and some of the operations described below can be replaced or eliminated, for additional embodiments of the method. The order of the operations/processes may be interchangeable, or two or more operations can be performed simultaneously. To simplify the explanation, descriptions of content that overlaps with the description of FIGS. 2 and 3A-3C are omitted.

Referring to FIGS. 2 and 4A to 4C, a plurality of first bit lines BL1 may be formed on a substrate 100 separated from each other in the second direction D2. In some example embodiments, forming the first bit lines BL1 may include depositing a bit line layer and patterning the bit line layer to form the first bit lines BL1.

Lower spacers 105 may be formed on the substrate 100 and between the first bit lines BL1. In some example embodiments, forming the lower spacers 105 may include forming a lower spacer layer and planarizing the lower spacer layer until upper surfaces of the first bit lines BL1 are exposed. For example, the planarization may be performed through a chemical mechanical polishing (CMP) process or an etch back process.

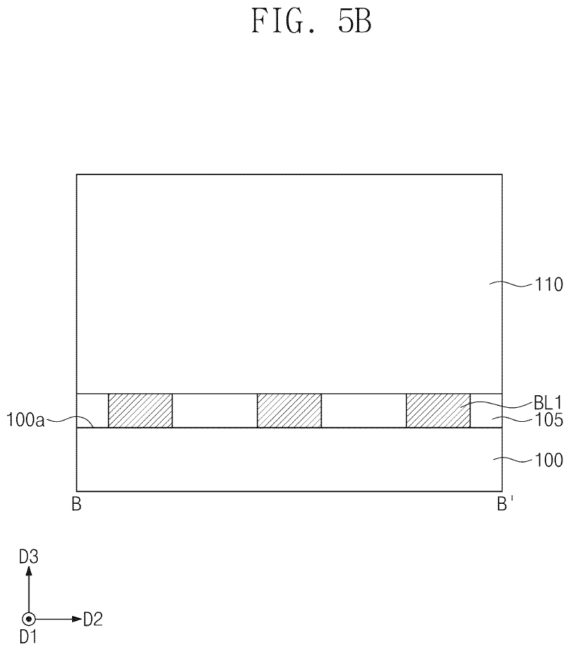

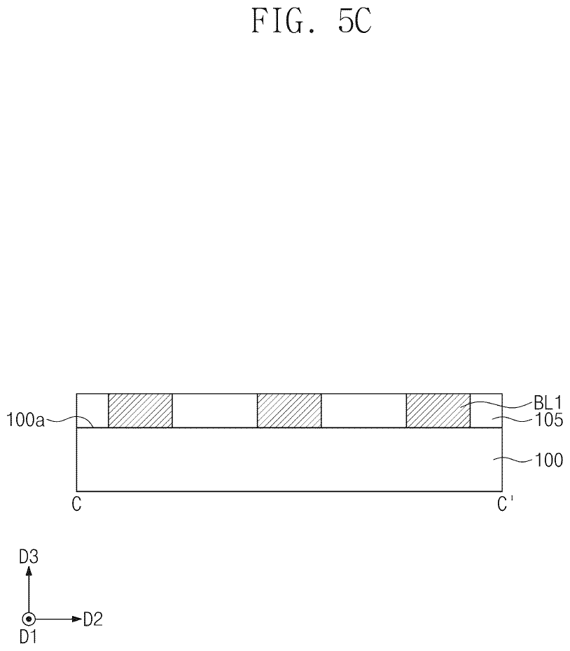

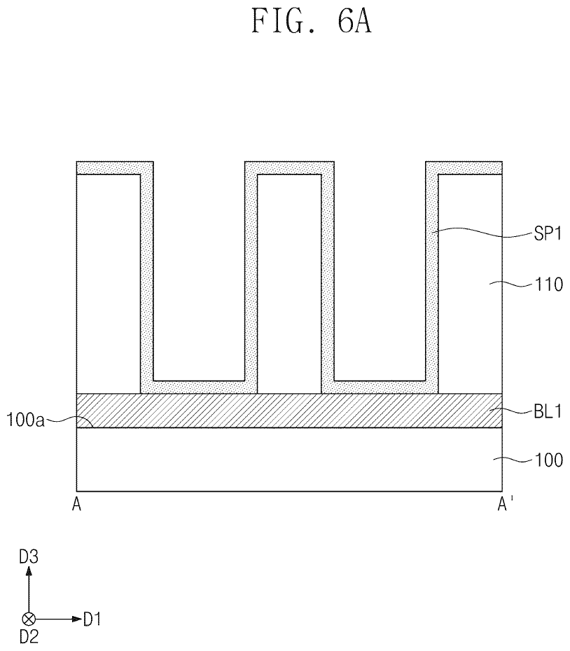

Referring to FIGS. 3 and 5A to 5C, a first insulating pattern 110 may be formed. In some example embodiments, forming the first insulating pattern 110 may include forming a first insulating pattern layer, forming a mask pattern on the first insulating pattern layer, etching the first insulating pattern layer using an etch mask, and removing the mask pattern. A plurality of first insulating patterns 110 may be formed. The first insulating patterns 110 may extend in the second direction D2 and be spaced apart from each other in the first direction D1.

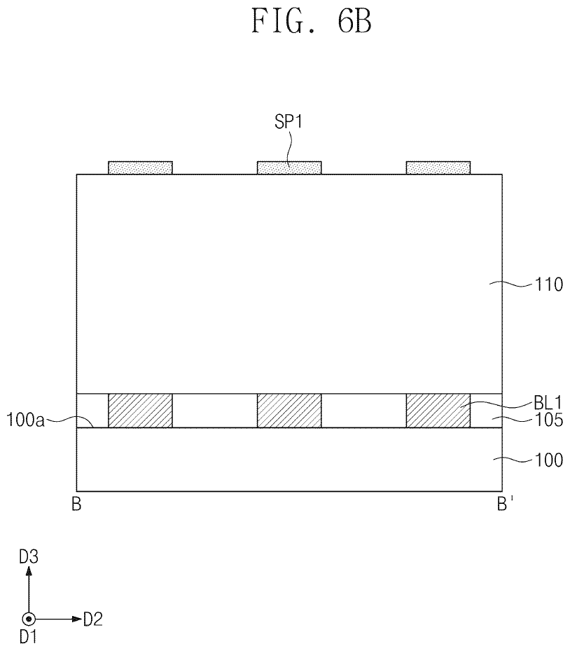

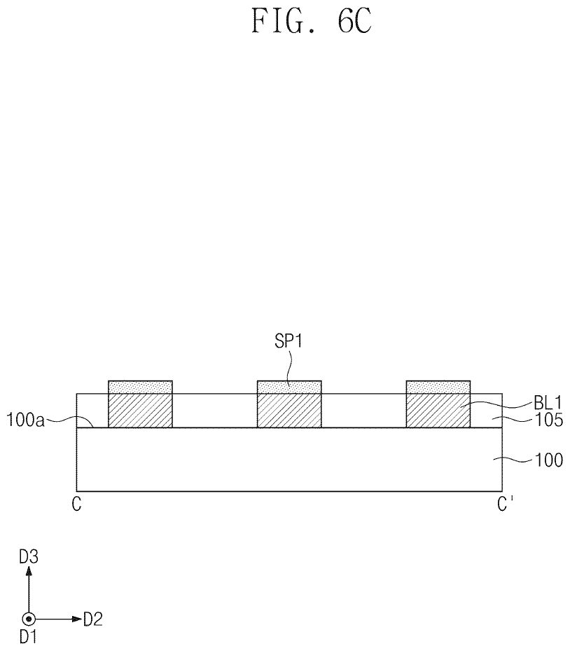

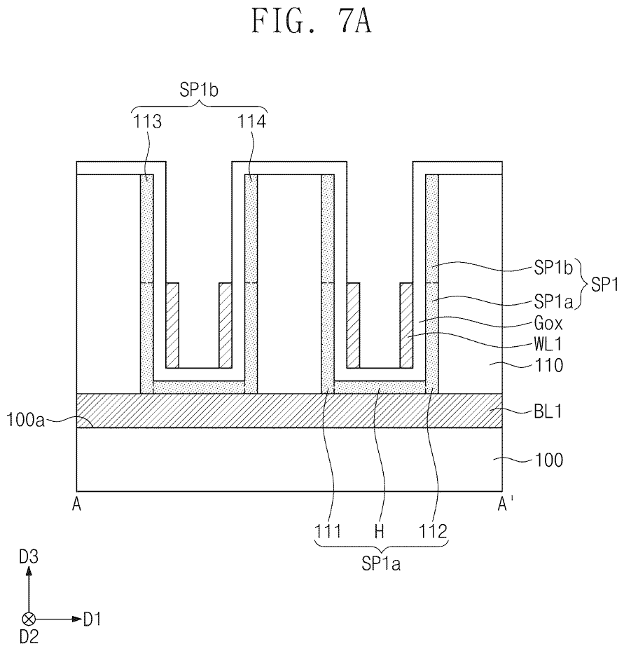

Referring to FIGS. 2 and 6A to 6C, a plurality of first semiconductor patterns SP1 may be formed. The first semiconductor pattern SP1 may conformally cover surfaces of the first insulating pattern 110. The first semiconductor pattern SP1 may extend on the upper surface of the first bit line BL1 exposed between the first insulating patterns 110. When viewed in a plan view, each of the first semiconductor patterns SP1 may extend in the first direction D1. The first semiconductor patterns SP1 may be spaced apart from each other in the second direction D2. The first semiconductor patterns SP1 may vertically overlap the first bit lines BL1.

In some example embodiments, forming the first semiconductor pattern SP1 may include, for example, forming a first semiconductor layer covering the entire surface of the substrate 100, forming a mask pattern on the first semiconductor layer, patterning a first semiconductor layer using the mask pattern as an etch mask, and removing the mask pattern. In some example embodiments, the first semiconductor layer may be formed using at least one of physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD).

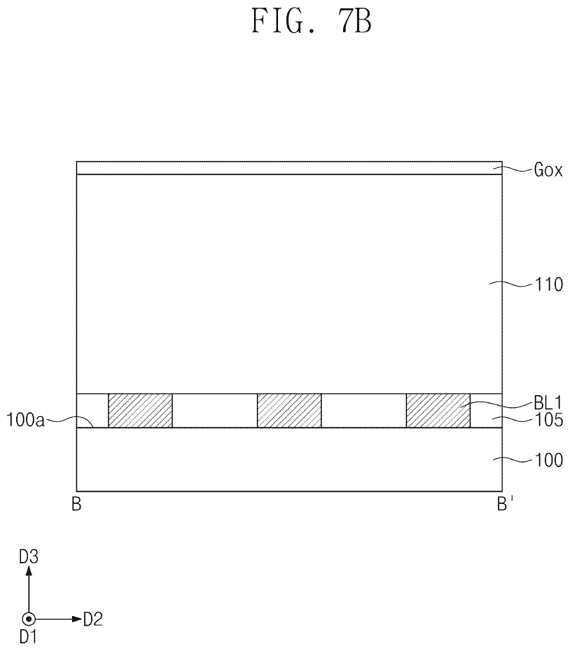

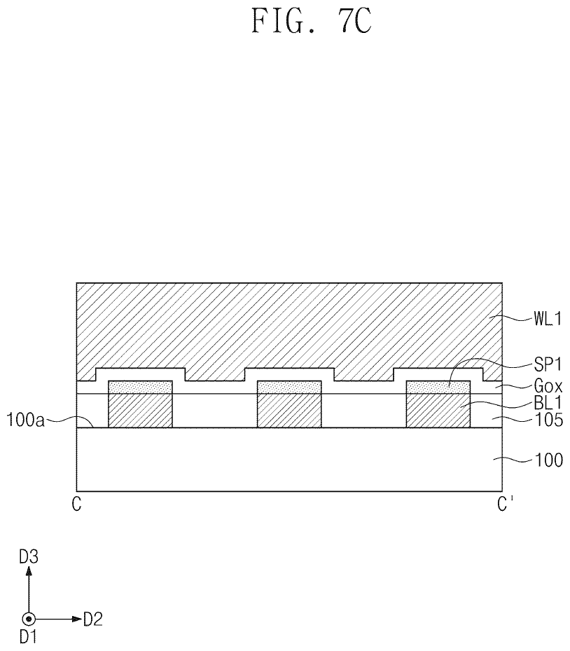

Referring to FIGS. 2 and 7A to 7C, a portion of the first semiconductor pattern SP1 on the upper surface of the first insulating pattern 110 may be removed or etched. Accordingly, the first semiconductor patterns SP1 may be spaced apart from each other in the first direction D1 and the second direction D2. Each of the first semiconductor patterns SP1 may include a first portion SP1a and a second portion SP1b.

A gate insulating pattern Gox may be formed on the entire surface of the substrate 100. The gate insulating pattern Gox may be formed using a layer deposition technology that may provide improved step coating properties, such as chemical vapor deposition (CVD), physical vapor deposition (PVD), and atomic layer deposition (ALD). The gate insulating pattern Gox may be conformally formed on the entire surface of the substrate 100. The gate insulating pattern Gox may conformally cover inner surfaces of the first semiconductor pattern SP1 and extend onto the lower spacers 105 and the first insulating patterns 110.

First word lines WL1 may be formed on the gate insulating pattern Gox. In some example embodiments, forming the first word lines WL1 may include forming a first word line layer and then patterning the first word line layer.

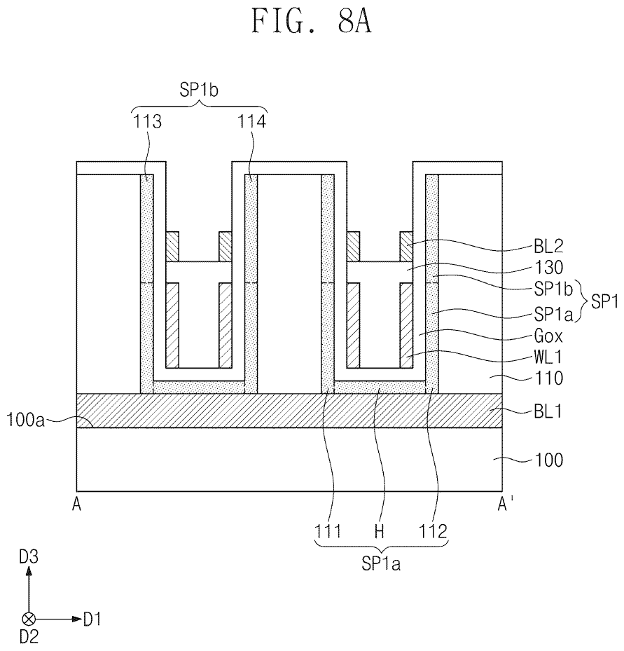

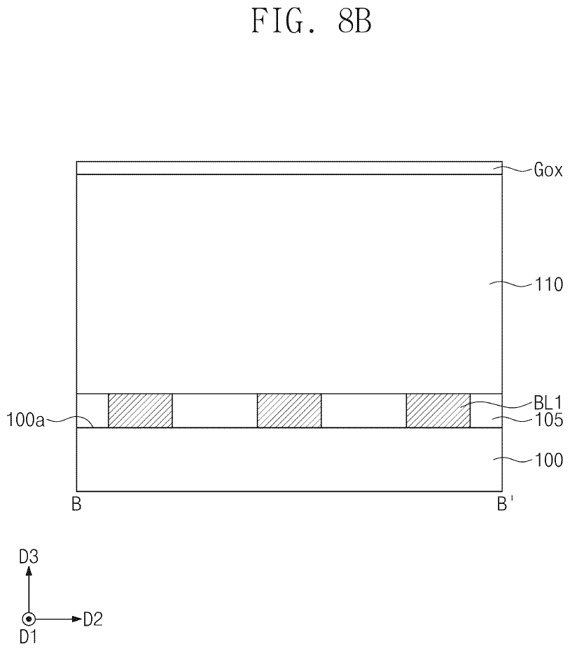

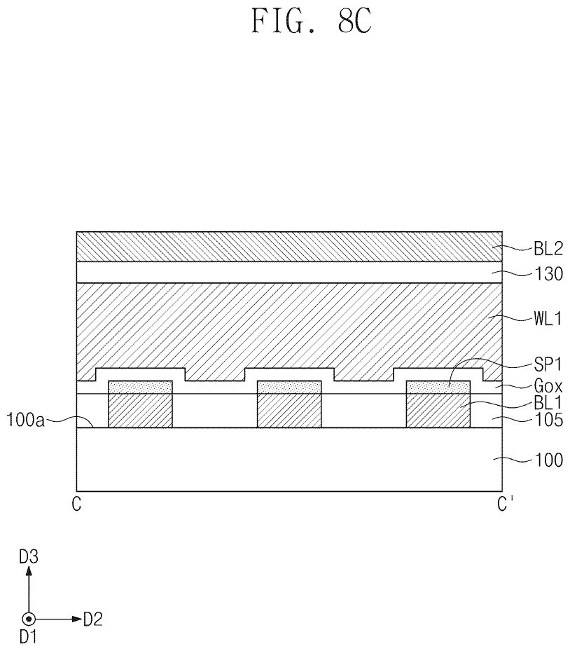

Referring to FIGS. 2 and 8A to 8C, a plurality of lower insulating patterns 130 may be formed between the first word lines WL1. The lower insulating patterns 130 may fill spaces between the first word lines WL1 spaced apart from each other in the first direction D1. In some example embodiments, forming the lower insulating patterns 130 may be performed using at least one of physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD).

Second bit lines BL2 may be formed on the lower insulating pattern 130. For example, forming the second bit lines BL2 may include forming a second bit line layer and patterning the second bit line layer. The second bit lines BL2 may vertically overlap the first word lines WL1 when viewed in a plan view. The first word lines WL1 and the second bit lines BL2 may extend in the second direction D2 crossing the first bit line BL1.

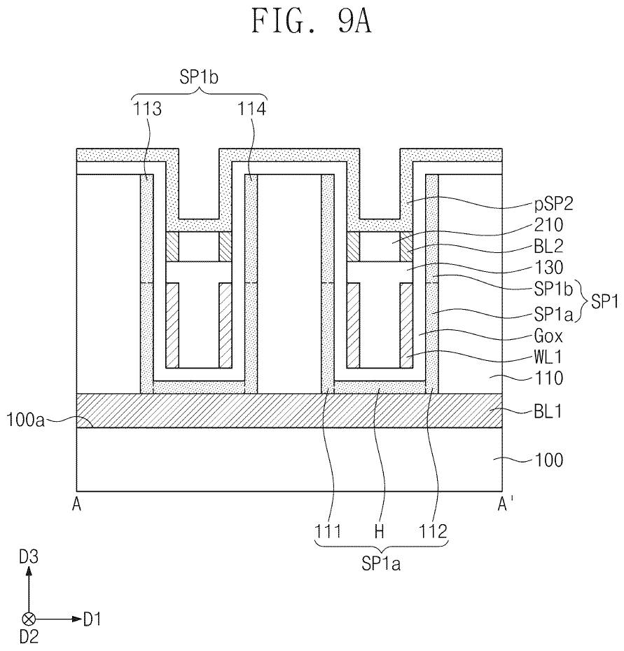

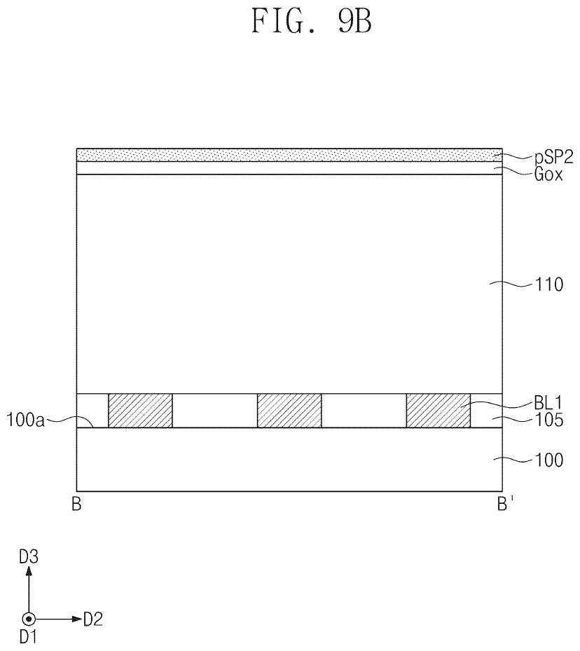

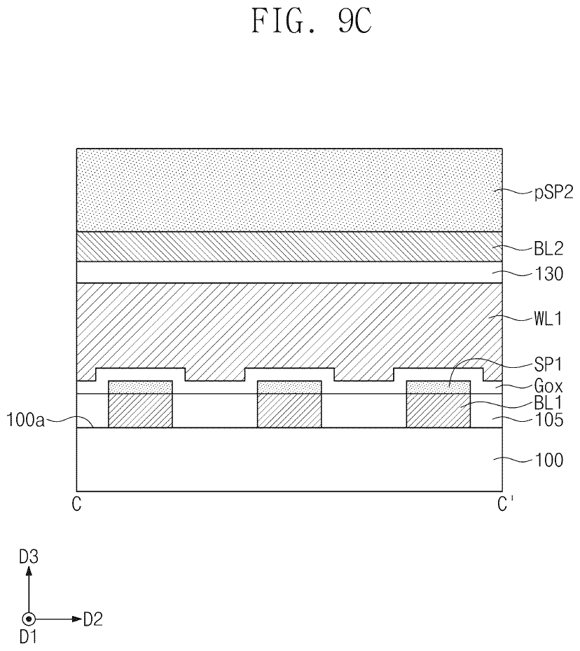

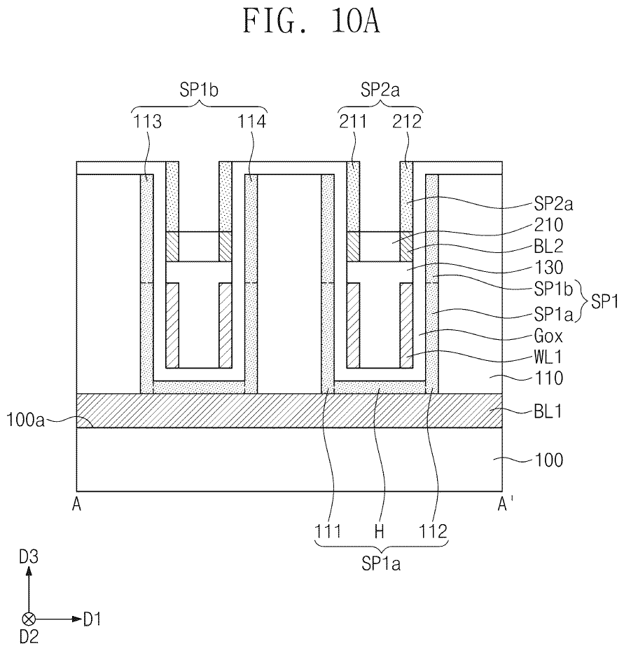

Referring to FIGS. 2 and 9A to 9C, a plurality of second insulating patterns 210 may be formed between corresponding adjacent second bit lines BL2. The second insulating pattern 210 may fill a space between the second bit lines BL2 spaced apart from each other in the first direction D1. In some example embodiments, forming the second insulating patterns 210 may be performed using at least one of physical vapor deposition (PVD), thermal chemical vapor deposition (thermal CVD), low pressure chemical vapor deposition (LP-CVD), plasma enhanced chemical vapor deposition (PE-CVD), and atomic vapor deposition (ALD). In some example embodiments, an upper surface of the second insulating pattern 210 may be coplanar with upper surfaces of the second bit lines BL2.

A second semiconductor layer pSP2 may be formed on the gate insulating pattern Gox, the second bit lines BL2, and the second insulating pattern 210. The second semiconductor layer pSP2 may be formed to cover the entire surface of the substrate 100. A portion of the second semiconductor layer pSP2 may be in direct contact with the second bit lines BL2. According to some example embodiments, the second semiconductor layer pSP2 may include an oxide semiconductor. According to some example embodiments, the second semiconductor layer pSP2 may include doped polycrystalline silicon.

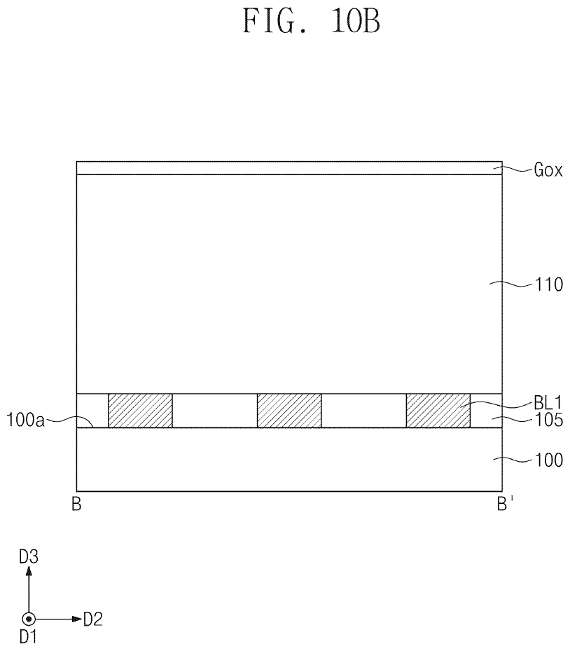

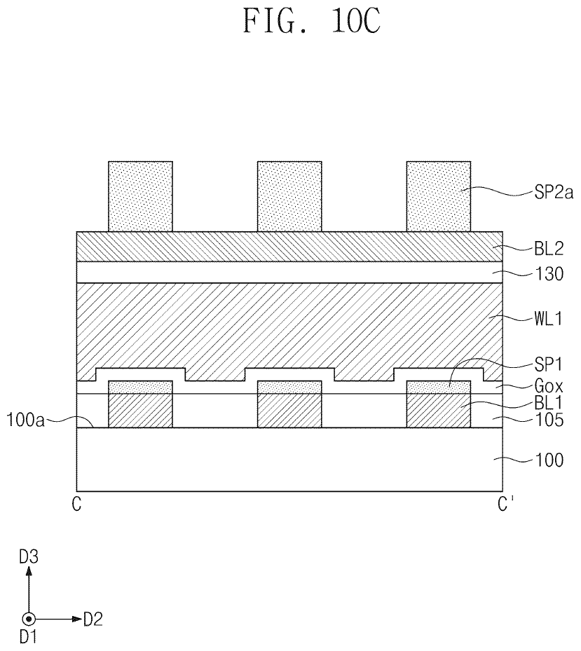

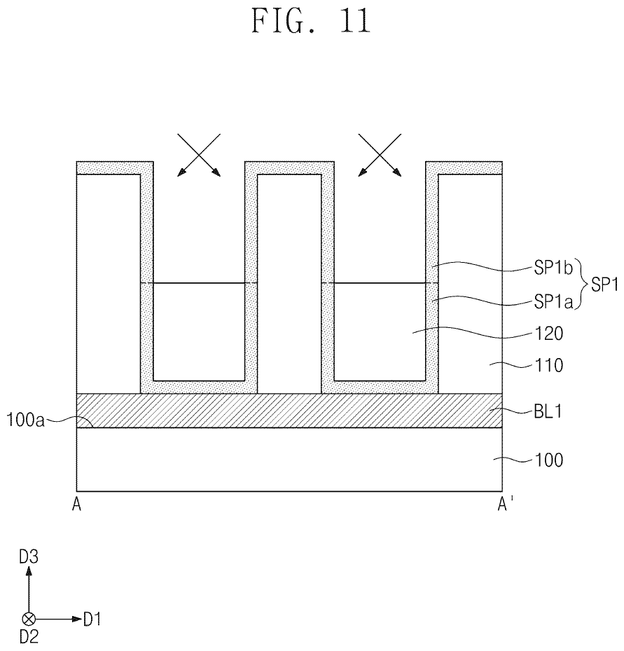

Referring to FIGS. 2 and 10A to 10C, upper vertical portions SP2a of the second semiconductor pattern SP2 may be formed. The upper vertical portions SP2a may be spaced apart from each other in the first direction D1. In some example embodiments, forming the upper vertical portions SP2a may be performed by removing a portion of the second semiconductor layer pSP2. In some example embodiments, removing portion of the second semiconductor layer pSP2 may be performed using an anisotropic etching process.

Referring again to FIGS. 2 and 3A to 3C, an upper insulating pattern 230 may be formed between the upper vertical portions SP2a of the second semiconductor pattern SP2. A plurality of upper insulating patterns 230 may be formed, and each upper insulating patterns 230 may fill a space between the adjacent upper vertical portions SP2a spaced apart from each other in the first direction D1. In some example embodiments, forming the upper insulating patterns 230 may be performed using at least one of physical vapor deposition (PVD), thermal chemical vapor deposition (thermal CVD), low pressure chemical vapor deposition (LP-CVD), plasma enhanced chemical vapor deposition (PE-CVD), and atomic layer deposition (ALD). An upper surface of the upper insulating pattern 230 may be coplanar with upper surfaces of the upper vertical portions SP2a.

An upper horizontal portion SP2b of the second semiconductor pattern SP2 may be formed on the gate insulating pattern Gox, the upper vertical portions SP2a, and the upper insulating pattern 230. In some example embodiments, forming the upper horizontal portion SP2b may include forming an upper horizontal layer and patterning the upper horizontal layer.

A second word line WL2 may be formed on the upper horizontal portion SP2b of the second semiconductor pattern SP2. In some example embodiments, forming the second word line WL2 may include forming a second word line layer and patterning the second word line layer.

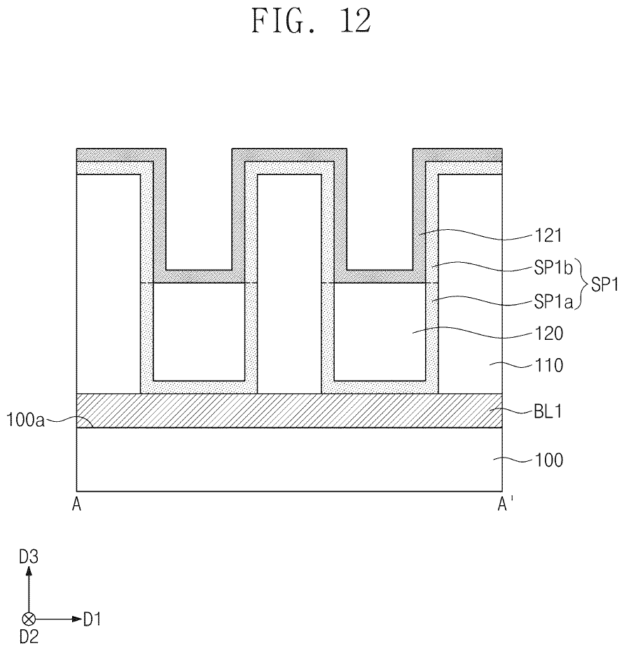

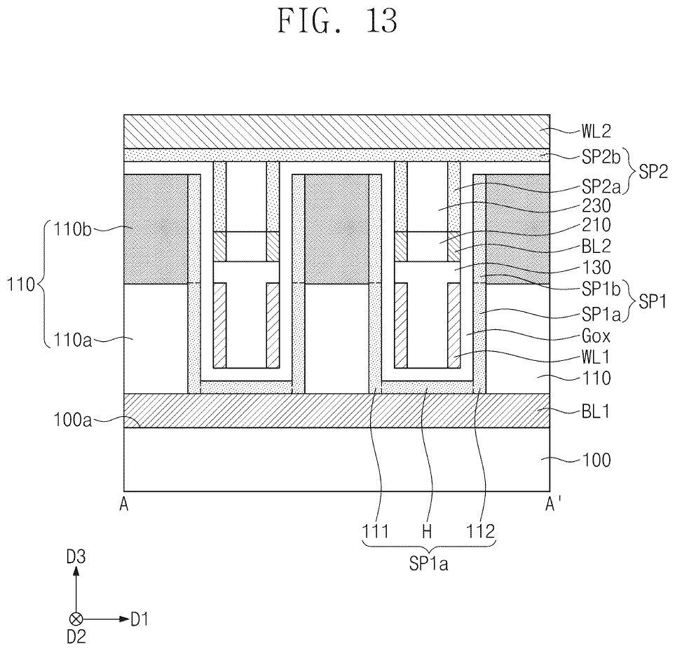

FIGS. 11 and 12 are cross-sectional views illustrating operations in a method of manufacturing a semiconductor device, according to some example embodiments of the inventive concepts. The operations of FIGS. 11 and 12 may be similar in some respects to the operations of FIGS. 4A-10C disclosed above, and therefore may be best understood with reference thereto where like numerals indicate like elements not described again in detail.

Referring to FIG. 11, according to some example embodiments, a first sacrificial layer 120 may be formed on inner surfaces of the first semiconductor pattern SP1 described with reference to FIGS. 6A to 6C. An upper surface of the first sacrificial layer 120 may be positioned at the same level as a boundary between the first portion SP1a and the second portion SP1b of the above-described first semiconductor pattern SP1. In For the purposes of discussion, the level may refer to a distance measured in the vertical direction D3 from an upper surface 100a of the substrate 100. The first sacrificial layer 120 may include, for example, silicon nitride.

After forming the first sacrificial layer 120, an implant process may be performed. The implant process may inject materials such as boron (B), argon (Ar), and/or fluorine (F), for example. The implant process may proceed with a tilt. The first sacrificial layer 120 may function as a mask, and a portion of the first semiconductor pattern SP1 blocked by the first sacrificial layer 120 may not be affected by the implant process. The second portion SP1b of the first semiconductor pattern SP1 may be damaged by the implant process. In this process, the first portion SP1a may not be damaged due to the implant process. Oxygen may escape from the second portion SP1b due to damage through the implant process. As a result, an oxygen concentration of the second portion SP1b may be relatively lower compared to that of the first portion SP1a. Accordingly, the second portion SP1b may be relatively more metallic compared to the first portion SP1a.

Referring to FIG. 12, a first sacrificial layer 120 may be formed on inner surfaces of the first semiconductor pattern SP1. A second sacrificial layer 121 may be formed to conformally cover the first semiconductor pattern SP1 and the first sacrificial layer 120. The second sacrificial layer 121 may be in direct contact with the second portion SP1b of the first semiconductor pattern SP1. The first portion SP1a may not be exposed by the first sacrificial layer 120, and the second sacrificial layer 121 may not be in contact with the first portion SP1a. The second sacrificial layer 121 may include, for example, boron (B). After forming the second sacrificial layer 121, boron (B) of the second sacrificial layer 121 may be diffused into the second portion SP1b through a thermal process. Accordingly, the second portion SP1b may be relatively more metallic compared to the first portion SP1a.

According to some example embodiments of FIGS. 11 and 12, the second portion SP1b of the first semiconductor pattern SP1 may be relatively more metallic compared to the first portion SP1a. In the semiconductor device according to some example embodiments, the second portion SP1b may be or include the gate of the read transistor.

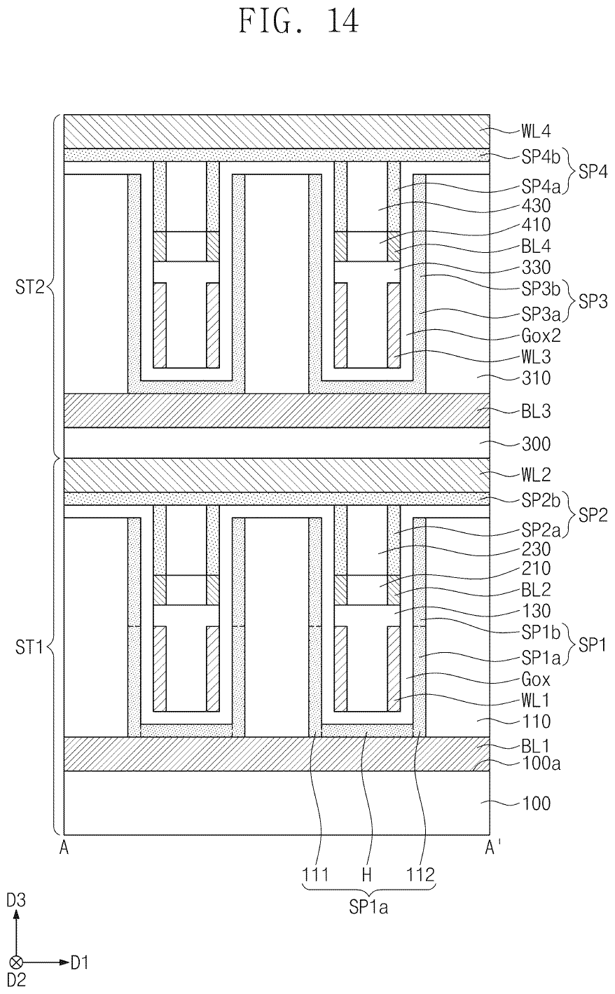

FIGS. 13 and 14 are cross-sectional views of semiconductor devices, according to some example embodiments of the inventive concepts. The semiconductor devices of FIGS. 13 and 14 may be the same in some respects to the semiconductor device of FIGS. 2-3C disclosed above, and therefore may be best understood with reference thereto where like numerals indicate like elements not described again in detail.

Referring to FIG. 13, a first insulating pattern 110 may include a lower pattern 110a (also referred to as a first portion) and an upper pattern 110b (also referred to as a second portion). The lower pattern 110a may be adjacent to the first portion SP1a of the first semiconductor pattern SP1. The upper pattern 110b may be adjacent to the second portion SP1b of the first semiconductor pattern SP1. According to some example embodiments, a boundary between the lower pattern 110a and the upper pattern 110b of the first insulating pattern 110 may be positioned at a same level as a boundary between the first portion SP1a and the second portion SP1b of the first semiconductor pattern SP1. An upper surface of the lower pattern 110a may be positioned at a same level as a boundary between the first portion SP1a and the second portion SP1b of the first semiconductor pattern SP1. An upper surface of the upper pattern 110b may be positioned at a same level as an upper surface of the third and fourth vertical portions 113 and 114 of the first semiconductor pattern SP1.

The lower pattern 110a and upper pattern 110b of the first insulating pattern 110 may include different materials. For example, the lower pattern 110a may include an oxide, and the upper pattern 110b may not include an oxide. According to some example embodiments, the lower pattern 110a may include silicon oxide, and the upper pattern 110b may include silicon nitride.

In the example embodiments of FIG. 13, a difference in oxygen concentration between the first portion SP1a and the second portion SP1b of the first semiconductor pattern SP1 may occur through a thermal process. In some example embodiments, after forming the first insulating pattern 110 and the first semiconductor pattern SP1, a thermal process may be performed that may cause a difference in the oxygen concentration. As the lower pattern 110a contains oxide, the first portion SP1a in direct contact with the lower pattern 110a may cause oxygen in the lower pattern 110a to diffuse into the first portion SP1a through a thermal process. As the upper pattern 110b in direct contact with the second portion SP1b does not contain oxide, oxygen may not diffuse into the second portion SP1b when a thermal process is performed. Accordingly, the oxygen concentration of the second portion SP1b may be relatively lower compared to that of the first portion SP1a. As a result, the second portion SP1b may be relatively more metallic compared to the first portion SP1a.

Referring to FIG. 14, the semiconductor device described above with reference to FIGS. 2 and 3A to 3C may form (or constitute) a first structure ST1. A second structure ST2 that is substantially the same as the first structure ST1 may be stacked on the first structure ST1 in the vertical direction D3.

The second structure ST2 may include a second substrate 300, a third bit line BL3, a third insulating pattern 310, a third semiconductor pattern SP3, a second gate insulating pattern Gox2, third word lines WL3, second lower insulating pattern 330, fourth bit lines BL4, a fourth insulating pattern 410, a fourth semiconductor pattern SP4, a second upper insulating pattern 430, and a fourth word line WL4. These may be substantially the same as the substrate 100, the first bit line BL1, the first insulating pattern 110, the first semiconductor pattern SP1, the gate insulating pattern Gox, the first word lines WL1, the lower insulating pattern 130, the second bit lines BL2, the second insulating pattern 210, the second semiconductor pattern SP2, the upper insulating pattern 230, and the second word line WL2, described above with reference to FIGS. 2 and 3A to 3C, respectively. In addition, the first portion SP3a and the second portion SP3b of the third semiconductor pattern SP3 may be substantially the same as the first portion SP1a and the second portion SP1b of the first semiconductor pattern SP1. The upper vertical portions SP4a and the upper horizontal portion SP4b of the fourth semiconductor pattern SP4 may be substantially the same as the upper vertical portions SP2a and the upper horizontal portion SP2b of the second semiconductor pattern SP2. The second structure ST2 may be manufactured using substantially the same process as described above with reference to FIGS. 4A to 10C.

According to some example embodiments, the second structure ST2 may be stacked on the first structure ST1 through deposition. According to some example embodiments, the second structure ST2 may be bonded to the first structure ST1. A plurality of structures identical to the first structure ST1 may be stacked on the first structure ST1. In some other example embodiments, other methods of stacking a plurality of structures may be used to stack the first and second structures ST1 and ST2.

According to example embodiments of the inventive concepts, as the semiconductor device does not include a capacitor, the area of the semiconductor device may be reduced. Accordingly, a relatively higher integration is possible. Additionally, because the gate may have a structure that surrounds the channel in three directions, the electrical characteristics and/or reliability of the transistor may be improved.

While several embodiments have been provided in the present disclosure, it should be understood that the example embodiments may be embodied in many other forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor device, comprising:
a first bit line extending in a first direction on a substrate;
a first semiconductor pattern on the first bit line, the first semiconductor pattern including vertical portions facing each other in the first direction and a horizontal portion connecting the vertical portions to each other;
first word lines spaced apart from each other in the first direction on the horizontal portion and extending in a second direction that is parallel to an upper surface of the substrate and intersects the first direction;
second bit lines spaced apart from each other in the first direction and on the first word lines, the second bit lines extending in the second direction;
a gate insulating pattern between the vertical portions of the first semiconductor pattern and the first word lines and extending between the vertical portions and the second bit lines;
a second semiconductor pattern on the second bit lines; and
a second word line extending in the first direction on the second semiconductor pattern,
wherein the first word lines and the second bit lines vertically overlap each other.

2. The semiconductor device of claim 1, wherein the vertical portions of the first semiconductor pattern include:
a first vertical portion and a second vertical portion adjacent to the first word lines; and
a third vertical portion and a fourth vertical portion adjacent to the second bit lines,
wherein the first vertical portion and the second vertical portion have a higher oxygen concentration than the third vertical portion and the fourth vertical portion.

3. The semiconductor device of claim 2, wherein the first vertical portion and the second vertical portion are crystalline, and
wherein the third vertical portion and the fourth vertical portion are amorphous.

4. The semiconductor device of claim 1, further comprising first insulating patterns on the first bit line and on outer surfaces of the vertical portions of the first semiconductor pattern, respectively,
wherein the first word lines are on inner surfaces of the vertical portions, respectively.

5. The semiconductor device of claim 4, wherein the vertical portions of the first semiconductor pattern include:
a first vertical portion adjacent to the first word lines and a second vertical portion adjacent to the first word lines; and
a third vertical portion adjacent to the second bit lines and a fourth vertical portion adjacent to the second bit lines,
wherein each of the first insulating patterns includes:
a first portion adjacent to the first and second vertical portions; and
a second portion adjacent to the third and fourth vertical portions,
wherein the first portion includes a material different from that of the second portion.

6. The semiconductor device of claim 5, wherein the first portion of each of the first insulating patterns includes an oxide, and
wherein the second portion of each of the first insulating patterns does not include an oxide.

7. The semiconductor device of claim 5, wherein the first and second vertical portions have a higher oxygen concentration than the third and fourth vertical portions.

8. The semiconductor device of claim 1, wherein the first semiconductor pattern includes an oxide semiconductor, and
wherein the second semiconductor pattern includes doped polycrystalline silicon.

9. The semiconductor device of claim 1, wherein the first bit line, the first semiconductor pattern, the first word lines, the second bit lines, the gate insulating pattern, the second semiconductor pattern, and the second word line constitute a first structure, and
wherein a plurality of the first structures are stacked in a vertical direction perpendicular to the upper surface of the substrate.

10. The semiconductor device of claim 1, wherein the first word lines and the second bit lines are vertically spaced apart from each other with a lower insulating pattern therebetween.

11. The semiconductor device of claim 1, wherein the second semiconductor pattern includes upper vertical portions extending in a vertical direction perpendicular to the upper surface of the substrate and an upper horizontal portion extending in the first direction on the upper vertical portions, and
wherein the upper vertical portions of the second semiconductor pattern are spaced apart from each other in the first direction.

12. The semiconductor device of claim 1, wherein each of the vertical portions of the first semiconductor pattern has side surfaces facing each other in the second direction, and
wherein each of the first word lines extends in the second direction on each inner surface of the vertical portions and covers the side surfaces of each of the vertical portions.

13. A semiconductor device comprising:
a first bit line extending in a first direction on a substrate;
a first semiconductor pattern extending on the first bit line in a vertical direction perpendicular to an upper surface of the substrate;
a first word line extending on an inner surface of the first semiconductor pattern in a second direction that is parallel to the upper surface of the substrate and intersects the first direction;
a second bit line spaced apart from the first word line in the vertical direction and extending in the second direction on the inner surface of the first semiconductor pattern;
a gate insulating pattern between the first semiconductor pattern and the first word line and between the first semiconductor pattern and the second bit line;
a second semiconductor pattern on the second bit line; and
a second word line extending in the first direction on the second semiconductor pattern,
wherein the first word line and the second bit line overlap each other in the vertical direction.

14. The semiconductor device of claim 13, wherein the first semiconductor pattern includes a first portion adjacent to the first word line and a second portion adjacent to the second bit line, and
wherein the first portion of the first semiconductor pattern has a higher oxygen concentration than the second portion of the first semiconductor pattern.

15. The semiconductor device of claim 14, further comprising a first insulating pattern on the first bit line and on an outer surface of the first semiconductor pattern,
wherein the first insulating pattern includes a lower pattern adjacent to the first portion of the first semiconductor pattern and an upper pattern adjacent to the second portion of the first semiconductor pattern.

16. The semiconductor device of claim 13, wherein the first semiconductor pattern has side surfaces facing each other in the second direction, and
wherein the first word line extends in the second direction on the inner surface of the first semiconductor pattern and covers the side surfaces of the first semiconductor pattern.

17. A semiconductor device comprising:
a first bit line extending in a first direction on a substrate;
first insulating patterns on the first bit line and spaced apart from each other in the first direction;
a first semiconductor pattern on the first bit line and between the first insulating patterns, the first semiconductor pattern including vertical portions extending in a vertical direction perpendicular to an upper surface of the substrate and facing each other in the first direction, and a horizontal portion connecting the vertical portions to each other;
first word lines spaced apart from each other in the first direction and on the horizontal portion, the first word lines extending in a second direction parallel to the upper surface of the substrate and intersecting the first direction;
second bit lines spaced apart from each other in the first direction on the first word lines and extending in the second direction;
a gate insulating pattern between the vertical portions of the first semiconductor pattern and the first word lines, between the vertical portions of the first semiconductor pattern and the second bit lines, and extending on the horizontal portion;
a second semiconductor pattern on the second bit lines; and
a second word line extending in the first direction on the second semiconductor pattern,
wherein the first word lines and the second bit lines are spaced apart from each other in the vertical direction and have a lower insulating pattern therebetween, the lower insulating pattern covering the first word lines, and
wherein the first word lines and the second bit lines overlap each other in the vertical direction.

18. The semiconductor device of claim 17, wherein the vertical portions of the first semiconductor pattern include:
a first vertical portion and a second vertical portion adjacent to each of the first word lines; and
a third vertical portion and a fourth vertical portion adjacent to each of the second bit lines,
wherein the first and second vertical portions have a higher oxygen concentration than the third and fourth vertical portions.

19. The semiconductor device of claim 18, wherein each of the first insulating patterns includes:
a first portion adjacent to the first and second vertical portions and including an oxide; and
a second portion adjacent to the third and fourth vertical portions and not including an oxide.

20. The semiconductor device of claim 17, wherein each of the vertical portions of the first semiconductor pattern has side surfaces facing each other in the second direction, and
wherein each of the first word lines extends in the second direction on each inner surface of the vertical portions and covers the side surfaces of each of the vertical portions.
